(19) United States
(12) Patent Application Publication
(10) Pub. No.: US 2004/0166675 A1
(43) Pub. Date: Aug. 26, 2004

(54) Manufacturing method of electro line for semiconductor device

(76) Inventor: Oh-Nam Kwon, Suwon-si (KR)

Correspondence Address: MCKENNA LONG & ALDRIDGE LLP, Song K. Jung, 1900 K Street, N.W., Washington, DC, 20006, US

(21) Appl. No.: 10/786,038

(22) Filed: Feb. 26, 2004

(30) Foreign Application Priority Data
Feb. 26, 2003 (KR) 2003-0011885

(51) Int. Cl. H01L 29/76

(52) U.S. Cl. 438/687

(57) ABSTRACT

A method of manufacturing an electro line for a semiconductor device includes depositing a molybdenum (Mo) layer on a substrate, depositing a copper layer (Cu) on the Mo layer, forming a photoresist pattern on the Cu layer, etching the Cu layer and the Mo layer using an etchant to form a Mo/Cu electro line, wherein the photoresist pattern is used as a patterning mask, and removing Mo residue around the Mo/Cu line to reduce short circuits between electro-lines and leakage current in the thin-film transistor.

The present invention claims the benefit of Korean Patent Application No. 2003-0011885 filed in Korea on Feb. 26, 2003, which is hereby incorporated by reference for all purposes as if fully set forth herein.

### BACKGROUND OF THE INVENTION

1. Field of the Invention

The present invention relates to a semiconductor device and more particularly, to a manufacturing method of an electro line for a semiconductor device.

2. Discussion Of The Related Art

A liquid crystal display (LCD) device, which is a kind of semiconductor device, has an electro line. The LCD device is widely used for notebook computers and desktop monitors, etc. because of its superior resolution, color image display and quality of displayed images.

In general, a liquid crystal display (LCD) device includes two substrates spaced apart and facing each other, and a liquid crystal material layer interposed between the two substrates. Each of the first and second substrates includes an electrode, whereby the electrodes of each of the first and second substrates face each other. When a voltage is applied to each of the electrodes, an electric field is induced between the electrodes. Accordingly, an alignment of the liquid crystal molecules of the liquid crystal material layer is changed by the varying intensity or direction of the induced electric field. Thus, the LCD device displays an image by varying the transmittance of light through the liquid crystal material layer based upon the arrangement of the liquid crystal molecules.

An active matrix LCD device, which has pixels arranged in a matrix type, has been widely used because of high resolution and fast moving images. An array substrate of the active matrix LCD device includes a plurality of thin film transistors (TFTs) and a plurality of pixel electrodes, each of which connects with each of the TFTs.

The LCD device includes a plurality of electro lines for applying signals, such as a plurality of gate lines and a plurality of data lines.

To improve reliability and competitive pricing of the LCD device, the gate and data lines are made of material having low resistivity such as aluminum (Al) or aluminum alloy to prevent signal delay. However, Al is easily corroded by acid.

Due to the large area and high resolution of LCD devices, such as Super Video Graphics Array (SVGA), Extended Graphics Array (XGA), Super Extended Graphics Array (SXGA), and VXGA, scanning time is shorter and signaling speeds are increasing. Therefore, copper (Cu), which has a lower resistivity than Al and has strong chemical corrosion resistance, has been proposed as a material for the gate and data lines.

However, Cu poorly adheres to a glass substrate, which is widely used as a substrate for the LCD devices, and is easily diffused into a layer including silicon in relatively low temperature of about 200 degrees.

To solve the above problem, a structure having another metal layer as a barrier layer has been proposed. The metal layer may be selected from one of titanium (Ti), molybdenum (Mo), chromium (Cr) and indium (In).

A related art LCD device will be described hereinafter in detail with reference to attached drawings. In the related art LCD device, Mo is used as a barrier layer.

FIG. 1A is a plan view of an array substrate for a related art liquid crystal display device. In FIG. 1A, a gate line 12 is formed along a first direction and a data line 20 is formed along a second direction. The gate and data lines 12 and 20 cross each other to define a pixel region P. At the crossing of the gate and data lines 12 and 20, a thin film transistor T is formed as a switching device, and the thin film transistor T is electrically connected to the gate and data lines 12 and 20. A pixel electrode 30 is formed in the pixel region P, and the pixel electrode 30 is connected to the thin film transistor T.

The thin film transistor T includes a gate electrode 14 extended from the gate line 12, an active layer 18 of an island shape overlapping the gate electrode 14, a source electrode 22 extended from the data line 20 and overlapping the active layer 18, and a drain electrode 24 spaced apart from the source electrode 22 and overlapping the active layer 18.

The gate line 12 and the data line 20 have a double-layered structure. Mo is used as an upper layer and Cu is used as a lower layer.

FIG. 1B is a cross-sectional view along the line II-II′ of FIG. 1A. In FIG. 1B, a gate electrode 14 is formed on a transparent substrate 10 and a gate insulating layer 16 is formed to cover the gate electrode 14. An active layer 18 made of amorphous silicon is formed on the gate insulating layer 16 and is positioned over the gate electrode 12. An ohmic contact layer 19 is formed on the active layer 18, and the ohmic contact layer 19 is made of doped amorphous silicon (for example, n+ a-Si). Source and drain electrodes 22 and 24 are formed on the ohmic contact layer 19 and spaced apart from each other. The active layer 18 exposed between the source and drain electrodes 22 and 24 is a channel CH of a thin film transistor T, which includes the gate electrode 14, the active layer 18, the source electrode 22 and the drain electrode 24.

The gate electrode 14, the source electrode 22 and the drain electrode 24 have a double-layered structure of Mo/Cu. Therefore, the gate electrode 14, the source electrode 22 and the drain electrode 24 include a first gate metal layer 14a, a first source metal layer 22a and a first drain metal layer 24a made of molybdenum (Mo), respectively. In addition, the gate electrode 14, the source electrode 22 and the drain electrode 24 include a second gate metal layer 14b, a second source metal layer 22b and a third drain metal layer 24b made of copper (Cu), respectively.

A passivation layer 28 is formed to cover the thin film transistor T, and the passivation layer 28 has a drain contact hole 26 exposing the drain electrode 24. A pixel electrode 30 is formed in a pixel region P on the passivation layer 26 and is connected to the drain electrode 24 through the drain contact hole 26.

The gate line including the gate electrode and the data line including the source and drain electrodes, which have a Mo/Cu double-layered structure, are formed through a photolithographic process using an etchant including hydrogen peroxide (H₂O₂). However, leakage currents increase and short-circuits occur because of Mo residue.

FIGS. 2A and 2B are scanning electron microscope (SEM) photographs showing a Mo/Cu electro line before stripping a photoresist pattern in a photolithographic process according to the related art. FIG. 2A is a perspective view of the Mo/Cu electro line and FIG. 2B is a plan view of the Mo/Cu electro line.

In FIGS. 2A and 2B, a molybdenum (Mo) layer and a copper (Cu) layer have thicknesses of about 100 Å and 2,000 Å, respectively, and a photoresist pattern is formed thereon. The Mo layer and the Cu layer are etched by using the photoresist pattern as a patterning mask, thereby forming a Mo/Cu electro line A Mo residue remains around the

The gate electrode 14, the source electrode 22 and the drain electrode 24 have a double-layered structure of Mo/Cu. Therefore, the gate electrode 14, the source electrode 22 and the drain electrode 24 include a first gate metal layer 14a, a first source metal layer 22a and a first drain metal layer 24a made of molybdenum (Mo), respectively. In addition, the gate electrode 14, the source electrode 22 and the drain electrode 24 include a second gate metal layer 14b, a second source metal layer 22b and a third drain metal layer 24b made of copper (Cu), respectively.

A passivation layer 28 is formed to cover the thin film transistor T, and the passivation layer 28 has a drain contact hole 26 exposing the drain electrode 24. A pixel electrode 30 is formed in a pixel region P on the passivation layer 26 and is connected to the drain electrode 24 through the drain contact hole 26.

The gate line including the gate electrode and the data line including the source and drain electrodes, which have a Mo/Cu double-layered structure, are formed through a photolithographic process using an etchant including hydrogen peroxide (H₂O₂). However, leakage currents increase and short-circuits occur because of Mo residue.

FIGS. 2A and 2B are scanning electron microscope (SEM) photographs showing a Mo/Cu electro line before stripping a photoresist pattern in a photolithographic process according to the related art. FIG. 2A is a perspective view of the Mo/Cu electro line and FIG. 2B is a plan view of the Mo/Cu electro line.

In FIGS. 2A and 2B, a molybdenum (Mo) layer and a copper (Cu) layer have thicknesses of about 100 Å and 2,000 Å, respectively, and a photoresist pattern is formed thereon. The Mo layer and the Cu layer are etched by using the photoresist pattern as a patterning mask, thereby forming a Mo/Cu electro line A Mo residue remains around the Mo/Cu electro line as illustrated in FIG. 2B. As stated above, the Mo residue causes short-circuits between electro lines and leakage currents in the thin film transistor T.

### SUMMARY OF THE INVENTION

Accordingly, the present invention is directed to a manufacturing method of an electro line for a semiconductor device that substantially obviates one or more problems due to limitations and disadvantages of the related art.

An advantage of the present invention is to provide a manufacturing method of an electro line for a semiconductor device, wherein the electro line has low resistivity and strong chemical corrosion resistance.

Another advantage of the present invention is to provide a manufacturing method of an electro line for a liquid crystal display (LCD) device having a large area and high resolution.

Additional features and advantages of the invention will be set forth in the description which follows, and in part will be apparent from the description, or may be learned by practice of the invention. The advantages of the invention will be realized and attained by the structure particularly pointed out in the written description and claims hereof as well as the appended drawings.

To achieve these and other advantages and in accordance with the purpose of the present invention, as embodied and broadly described, a method of manufacturing an electro line for a semiconductor device includes depositing a molybdenum (Mo) layer on a substrate; depositing a copper layer (Cu) on the Mo layer; forming a photoresist pattern on the Cu layer; etching the Cu layer and the Mo layer using an etchant to form a Mo/Cu electro line, wherein the photoresist pattern is used as a patterning mask; and removing Mo residue around the Mo/Cu electro line.

In another aspect of the present invention, a method of manufacturing a liquid crystal display device including a Mo/Cu line includes forming a gate line and a gate electrode including depositing a molybdenum (Mo) layer on a substrate, depositing a copper layer (Cu) on the Mo layer, forming a photoresist pattern on the Cu layer, etching the Cu layer and the Mo layer using an etchant, to form a Mo/Cu electro line, wherein the photoresist pattern is used as a patterning mask, and removing Mo residue around the Mo/Cu electro line; forming a gate insulating layer on the gate line and the gate electrode; forming a semiconductor layer on the gate insulating layer over the gate electrode; forming a data line, a source electrode and a drain electrode on the semiconductor layer; forming a passivation layer on the data line, the source electrode and the drain electrode; and forming a pixel electrode on the passivation layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1A is a plan view of an array substrate for a related art liquid crystal display device;

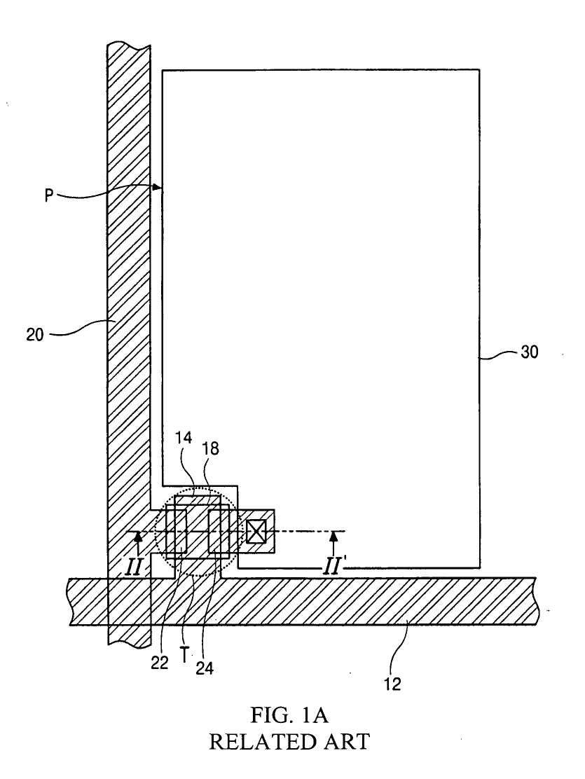

FIG. 1B is a cross-sectional view along the line II-II′ of FIG. 1A;

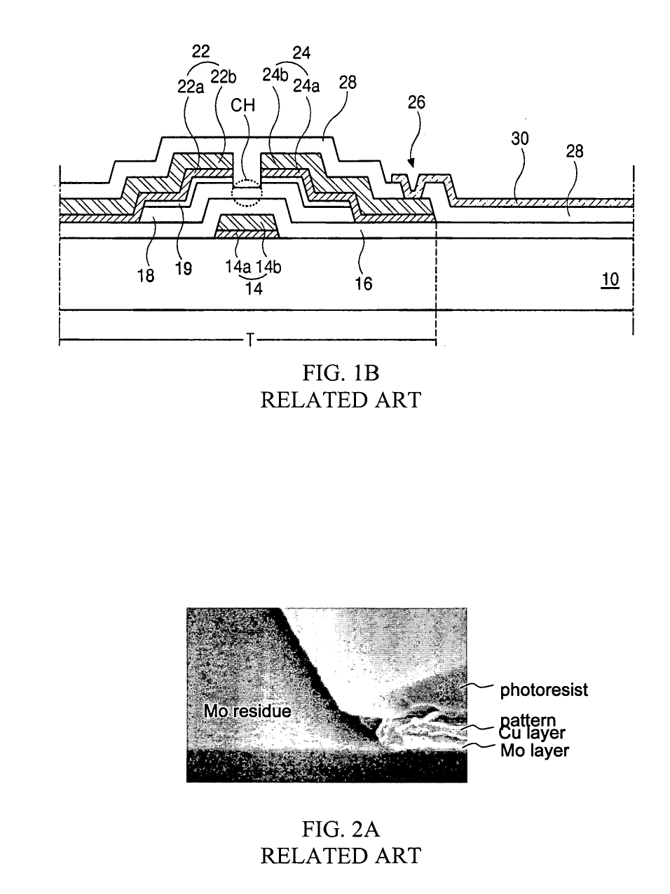

FIGS. 2A and 2B are scanning electron microscope (SEM) photographs showing a Mo/Cu electro line before stripping a photoresist pattern in a photolithographic process according to the related art;

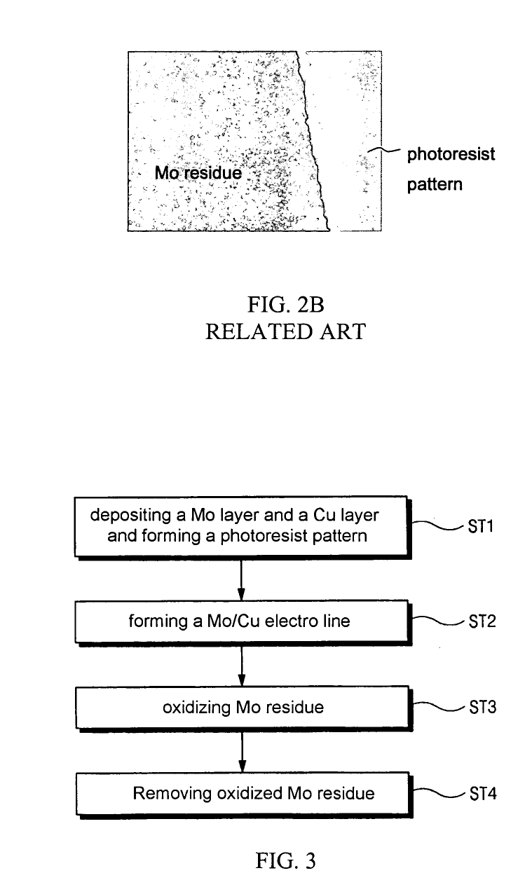

FIG. 3 is a flow chart illustrating a manufacturing process of a Mo/Cu electro line for a semiconductor device according to an embodiment of the present invention;

FIGS. 4A to 4C are scanning electron microscope (SEM) photographs illustrating a manufacturing process of a Mo/Cu electro line according to the embodiment of the present invention; and

FIG. 5 is a flow chart illustrating a process of fabricating an array substrate for a liquid crystal display device including a Mo/Cu electro line according to the embodiment of the present invention.

### DETAILED DESCRIPTION OF THE ILLUSTRATED EMBODIMENTS

Reference will now be made in detail to embodiments of the present invention, examples of which are illustrated in the accompanying drawings.

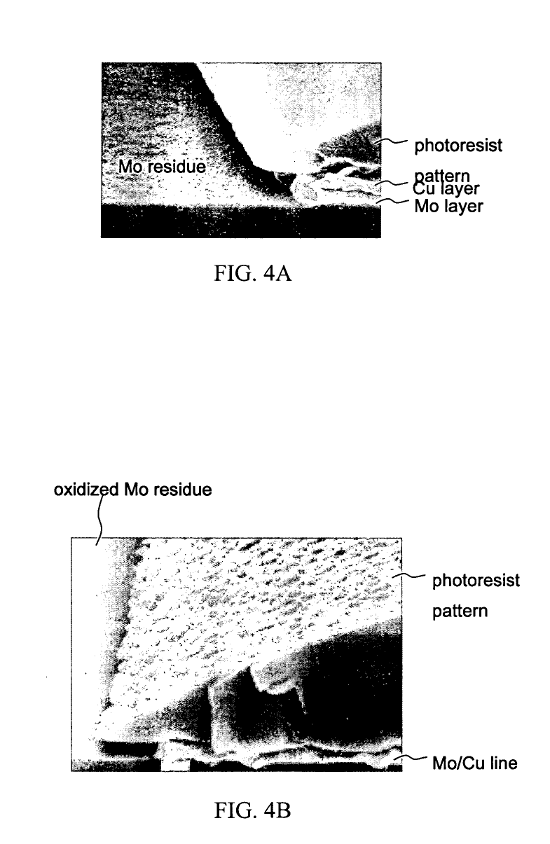

FIG. 3 is a flow chart illustrating a manufacturing process of a Mo/Cu electro line for a semiconductor device according to an embodiment of the present invention.

At ST1, a molybdenum (Mo) layer and a copper (Cu) layer are sequentially deposited on a substrate by a depositing method, such as sputtering, and a photoresist layer is coated to cover the Cu layer. The photoresist layer is selectively removed through a photolithographic process, in which the photoresist layer is exposed to light using a mask including blocking portions and openings, and then is developed, to form a photoresist pattern. The photoresist layer may be made of a photosensitive organic polymer or a mixture of a photosensitive material and a polymer. The photoresist layer may be a negative type in which a portion that has not been exposed to light is removed. The photoresist layer may be a positive type, in which a portion that has been exposed to light is removed.

At ST2, the Cu layer and the Mo layer are patterned using the photoresist pattern as a patterning mask. Thus, the Cu layer and the Mo layer not covered with the photoresist pattern are removed through a wet etching method using an etchant including hydrogen peroxide (H₂O₂), thereby forming a Mo/Cu electro line, for example, an electrical or signal line.

At ST3, a molybdenum (Mo) residue remains around the Mo/Cu electro line after the etching process of the step ST2, and the Mo residue is oxidized. The oxidization of the Mo residue may be performed through one of an oxygen (O₂) ashing process using O₂ plasma, an oxidization process using ultra violet (UV) light, and an annealing process using O₂ gas. The annealing process may be carried out under atmospheric conditions. In the annealing process, the Mo residue is oxidized with O₂ of the air by injecting O₂ gas to activate the reaction of Mo and O₂.

In ST4, the oxidized Mo residue is removed using one of stripper, deionized (DI) water, and dilute solution of hydrogen fluoride (HF). On the other hand, ozone (O₃) water may be used for removing the oxidized Mo residue. It is beneficial to strip the photoresist pattern together with the oxidized Mo residue.

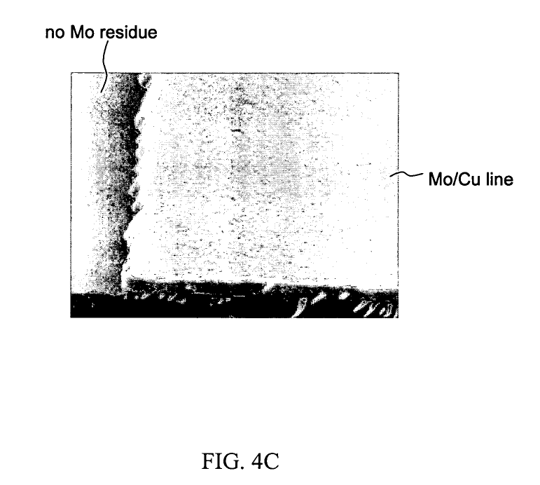

FIGS. 4A to 4C are scanning electron microscope (SEM) photographs illustrating a manufacturing process of a Mo/Cu electro line according to the embodiment of the present invention. In FIGS. 4A to 4B, a Mo layer may have a thickness of about 100 Å and a Cu layer may have a thickness of about 2,000 Å.

FIG. 4A shows a substrate including the Mo residue after etching the Mo layer and the Cu layer using the etchant including H₂O₂, wherein the photoresist pattern is used as a patterning mask. FIG. 4B shows the substrate including oxidized Mo residue. FIG. 4C shows the substrate after removing the oxidized Mo residue during a stripping process of the photoresist pattern.

In the related art, the Mo residue is not removed, and thus several problems are caused due to the Mo residue. However, in the present invention, because the Mo residue is oxidized and then removed, the problems may be prevented.

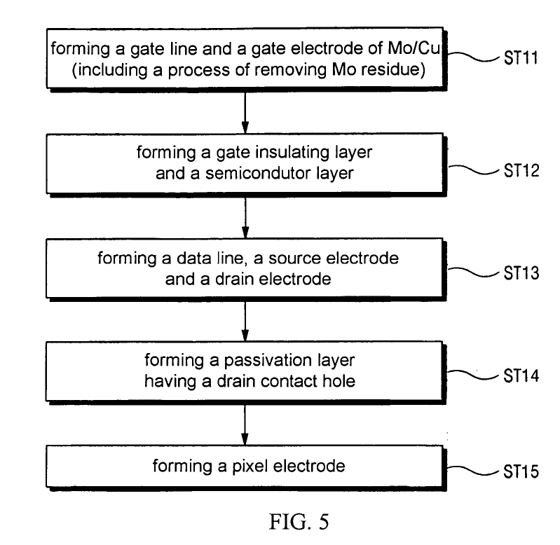

FIG. 5 is a flow chart illustrating a process of fabricating an array substrate for a liquid crystal display device including a Mo/Cu electro line according to the embodiment of the present invention.

During a step ST11, a gate line and a gate electrode are formed on a substrate, wherein the gate line and the gate electrode have a Mo/Cu double-layered structure. After the Mo layer and a Cu layer are deposited and then patterned, Mo residue is removed, whereby the gate line and the gate electrode are formed. The Mo layer improves adhesive strength between the substrate and the Cu layer. The Mo residue may be oxidized and then removed using one of stripper, deionized (DI) water, and dilute solution of hydrogen fluoride (HF). The Mo residue may be removed using ozone (O₃) water without oxidizing the Mo residue.

During ST12, a gate insulating layer is formed to cover the gate line and the gate electrode, and a semiconductor layer is formed on the gate insulating layer over the gate electrode. The semiconductor layer includes an active layer of amorphous silicon and an ohmic contact layer of doped amorphous silicon.

During ST13, a data line, a source electrode and a drain electrode are formed on the semiconductor layer. The data line crosses the gate line to define a pixel region. The source and drain electrodes are spaced apart over the semiconductor layer. The source electrode is connected to the data line. The ohmic contact layer exposed between the source and drain electrodes is removed, thereby exposing the active layer. The exposed active layer is a channel of a thin film transistor, which includes the gate electrode, the semiconductor layer, the source electrode and the drain electrode.

The data line and the source and drain electrodes are made of a metal material including copper (Cu). More beneficially, to prevent copper from diffusing into the semiconductor layer, the data line and the source and drain electrodes may have a Mo/Cu double-layered structure using Mo as a barrier layer. In a case of the Mo/Cu structure, the process for removing Mo residue is performed similar to the step ST11. Therefore, leakage currents may not be produced and short-circuits between the lines can be prevented.

In ST14, a passivation layer is formed to cover the thin film transistor. The passivation layer has a drain contact hole that exposes the drain electrode.

In ST15, a pixel electrode is formed in the pixel region on the passivation layer and is connected to the drain electrode through the drain contact hole.

In the present invention, since an electro line has a Mo/Cu double-layered structure, the electro line has low resistivity and a strong chemical corrosion resistance. In addition, Mo residue is removed after patterning the electro line, and thus leakage currents and short-circuits due to the Mo residue can be effectively prevented. Mo, which is used as a barrier layer, improves the adhesive strength between Cu from and a substrate and prevents Cu diffusing into a layer including silicon. Therefore, productivity of the device may be increased.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A method of manufacturing an electro line for a semiconductor device, comprising:
depositing a molybdenum (Mo) layer on a substrate;
depositing a copper layer (Cu) on the Mo layer;
forming a photoresist pattern on the Cu layer;
etching the Cu layer and the Mo layer using an etchant to form a Mo/Cu electro line, wherein the photoresist pattern is used as a patterning mask; and
removing Mo residue around the Mo/Cu electro line.

2. The method according to claim 1, wherein removing the Mo residue around the Mo/Cu electro line includes oxidizing the Mo residue and removing the oxidized Mo residue.

3. The method according to claim 2, wherein oxidizing the Mo residue includes one of an O₂ ashing process, an Ultra Violet treating process and an O₂ annealing process.

4. The method according to claim 2, wherein removing the oxidized Mo residue includes using one of stripper, deionized (DI) water, and dilute solution including hydrogen fluoride (HF).

5. The method according to claim 2, wherein removing the oxidized Mo residue further includes removing the photoresist pattern.

6. The method according to claim 1, wherein removing the Mo residue around the Mo/Cu electro line is performed using ozone (O₃) water.

7. The method according to claim 1, wherein the etchant includes hydrogen peroxide (H₂O₂).

8. A method of manufacturing a liquid crystal display device including a Mo/Cu electro line, comprising:
forming a gate line and a gate electrode, including:
depositing a molybdenum (Mo) layer on a substrate;
depositing a copper layer (Cu) on the Mo layer;
forming a photoresist pattern on the Cu layer;
etching the Cu layer and the Mo layer using an etchant to form a Mo/Cu electro line, wherein the photoresist pattern is used as a patterning mask; and
removing Mo residue around the Mo/Cu electro line;
forming a gate insulating layer on the gate line and the gate electrode;
forming a semiconductor layer on the gate insulating layer over the gate electrode;
forming a data line, a source electrode and a drain electrode on the semiconductor layer;
forming a passivation layer on the data line, the source electrode and the drain electrode; and
forming a pixel electrode on the passivation layer.

9. The method according to claim 8, wherein removing the Mo residue around the Mo/Cu electro line includes oxidizing the Mo residue and removing the oxidized Mo residue.

10. The method according to claim 9, wherein oxidizing the Mo residue includes one of an O₂ ashing process, an Ultra Violet treating process and an O₂ annealing process.

11. The method according to claim 9, wherein removing the oxidized Mo residue includes using one of stripper, deionized (DI) water, and dilute solution including hydrogen fluoride (HF).

12. The method according to claim 9, wherein removing the oxidized Mo residue further includes removing the photoresist pattern.

13. The method according to claim 8, wherein removing the Mo residue around the Mo/Cu electro line is performed using ozone (O₃) water.

14. The method according to claim 8, wherein the etchant includes hydrogen peroxide (H₂O₂).

15. The method according to claim 8, wherein forming a data line, a source electrode and a drain electrode on the semiconductor layer includes forming a Mo/Cu structure.

16. The method according to claim 15, wherein forming the Mo/Cu structure includes:
depositing a molybdenum (Mo) layer on a substrate;
depositing a copper layer (Cu) on the Mo layer;
forming a photoresist pattern on the Cu layer;
etching the Cu layer and the Mo layer using an etchant to form a Mo/Cu line, wherein the photoresist pattern is used as a patterning mask; and
removing Mo residue around the Mo/Cu line.
